(19) United States
(12) Patent Application Publication
(10) Pub. No.: US 2025/0385217 A1
(43) Pub. Date: Dec. 18, 2025

(54) BONDING APPARATUS AND A BONDING METHOD

(71) Applicant: STATS ChipPAC Pte. Ltd., Singapore (SG)

(72) Inventor: JongChan PARK, Incheon (KR)

(21) Appl. No.: 19/237,038

(22) Filed: Jun. 13, 2025

(30) Foreign Application Priority Data
Jun. 14, 2024 (CN) 202410765500.8

(51) Int. Cl. H01L 23/00; B23K 1/005; B23K 101/40

(52) U.S. Cl. CPC H01L 24/75; B23K 1/0056; H01L 24/81; B23K 2101/40; H01L 2224/75263; H01L 2224/81224

(57) ABSTRACT

A bonding apparatus is provided, which comprises: a jig configured for supporting a substrate at its periphery, wherein the substrate has a semiconductor die mounted thereon; a top cover operably attached to the jig and configured for covering the substrate and the semiconductor die, wherein the top cover comprises: a clamping component operably attached to the jig and configured for covering a portion of the substrate to reduce warpage of the substrate, wherein the clamping component comprises an opening configured for accommodating and exposing the semiconductor die; and a light pervious component mounted within the opening and configured for covering the semiconductor die to reduce warpage of the semiconductor die and allowing a laser beam to pass therethrough to the semiconductor die when the top cover is attached to the jig; and a laser source configured for emitting a laser beam that passes through the light pervious component.

### TECHNICAL FIELD

The present application generally relates to semiconductor technology, and more particularly, to a bonding apparatus and a bonding method.

### BACKGROUND OF THE INVENTION

In the semiconductor industry, laser assisted bonding (LAB) technology is widely used in chip assembling processes. During an LAB process, a laser source emits a laser beam to reflow solder bumps between a substrate and a semiconductor die, so as to bond the semiconductor die onto the substrate via the reflowed solder bumps. Typically, a large amount of heat is directly radiated to the semiconductor die and the substrate during the bonding process, which may induce warpage issues and may adversely affect the performance of a device so produced.

Therefore, a need exists for a bonding apparatus to bond a semiconductor die onto a substrate with reduced warpage.

### SUMMARY OF THE INVENTION

An objective of the present application is to provide a bonding apparatus to bond a semiconductor die onto a substrate with reduced warpage.

According to an aspect of the present application, a bonding apparatus is provided. The bonding apparatus comprises: a jig configured for supporting a substrate at its periphery, wherein the substrate has a semiconductor die mounted thereon; a top cover operably attached to the jig and configured for covering the substrate and the semiconductor die when the top cover is attached to the jig, wherein the top cover comprises: a clamping component operably attached to the jig and configured for covering a portion of the substrate to reduce warpage of the substrate when the top cover is attached to the jig, wherein the clamping component comprises an opening at its center and configured for accommodating and exposing the semiconductor die; and a light pervious component mounted within the opening and configured for covering the semiconductor die to reduce warpage of the semiconductor die and allowing a laser beam to pass therethrough to the semiconductor die when the top cover is attached to the jig; and a laser source configured for emitting a laser beam that passes through the light pervious component to the semiconductor die.

According to another aspect of the present application, a bonding method is provided, wherein the bonding method is implemented by a bonding apparatus comprising: a jig; a top cover above the jig, wherein the top cover comprises a clamping component having an opening, and a light pervious component disposed within the opening; and a laser source, and wherein the method comprises: placing a substrate having a semiconductor die mounted thereon between the top cover and the jig with the jig supporting the substrate at its periphery and the top cover attached to the jig, wherein the clamping component covers a portion of the substrate and the light pervious component covers the semiconductor die; and emitting a laser beam to the semiconductor die through the light pervious component via the laser source to bond the semiconductor die onto the substrate via solder bumps, wherein the clamping component presses a portion of the substrate against the jig to reduce warpage of the substrate and the light pervious component presses the semiconductor die against the substrate to reduce warpage of the semiconductor die.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a side view of a bonding apparatus during a bonding step according to a first embodiment of the present application.

FIG. 1B illustrates a top view of a jig of the bonding apparatus shown in FIG. 1A.

FIG. 1C illustrates a top view of a top cover of the bonding apparatus shown in FIG. 1A.

FIGS. 2A to 2C illustrate various steps of a bonding method implemented by a bonding apparatus according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in some chip assembling processes, laser assisted bonding (LAB) technology is used to bond a semiconductor die onto a package using an LAB bonding apparatus. During an LAB process implemented by such LAB bonding apparatus, a jig of the LAB bonding apparatus may support a substrate at its periphery, and a top cover of the LAB bonding apparatus can be further attached to the jig to cover a portion of the substrate. Then a laser source of the LAB bonding apparatus may emit a laser beam to reflow solder bumps between the substrate and the semiconductor die, so as to bond the semiconductor die onto the substrate via the reflowed solder bumps. During the bonding process, a large amount of heat is directly radiated from the laser source to the semiconductor die and the substrate and absorbed by them, while the jig and the top cover, as a combo, apply forces to the substrate to reduce warpage issue that may be induced from the heat radiation. However, it is noted by the inventors of the present application that the top cover of the existing LAB bonding apparatus has an opening at its center to accommodate the semiconductor die and expose the semiconductor die to the laser source, where no force can be applied, and thus warpage issues may still exist and cannot be resolved.

To address the above issue, in some embodiments, a new bonding apparatus is provided. The new bonding apparatus utilizes a light pervious component to press a semiconductor die and a substrate against a jig of the bonding apparatus, while allowing a laser beam from to pass therethrough to the semiconductor die. In this way, a sufficient amount of heat radiation can reach solder bumps between the semiconductor die and the substrate, and at the same time, warpage of the semiconductor die and the substrate can be further be reduced or even substantially avoided.

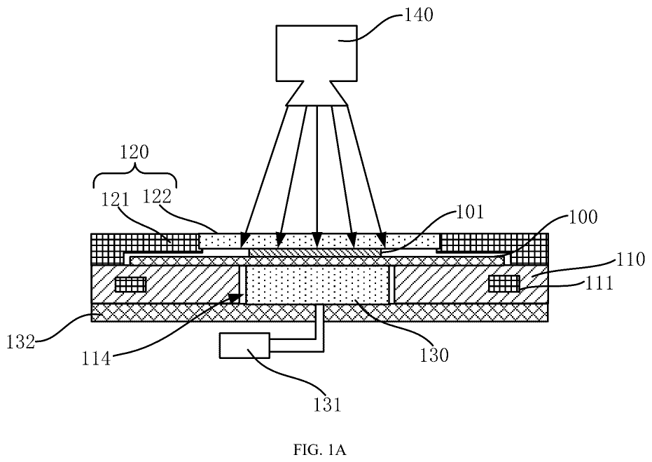

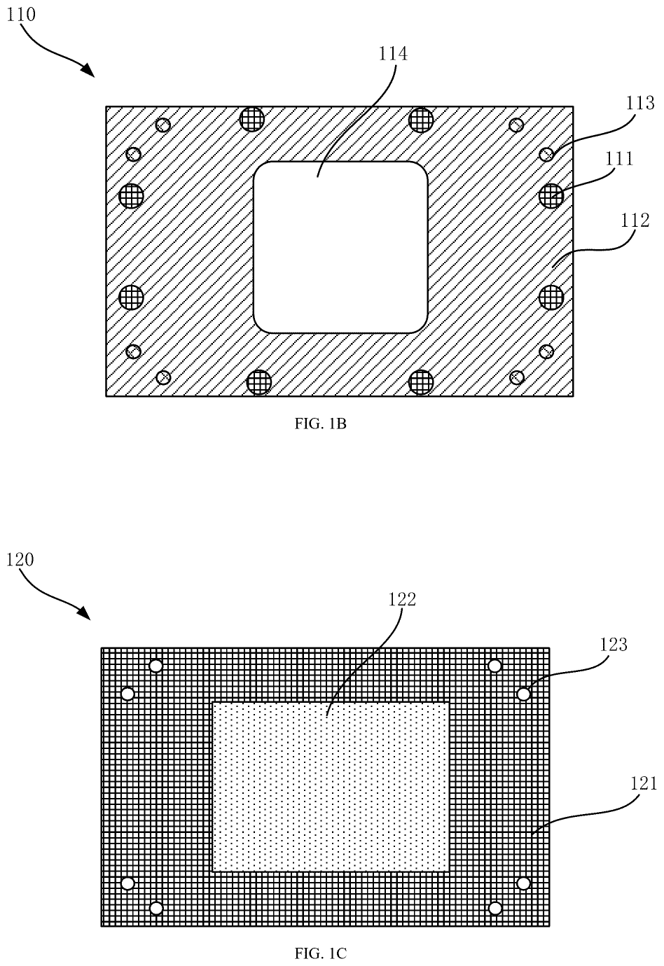

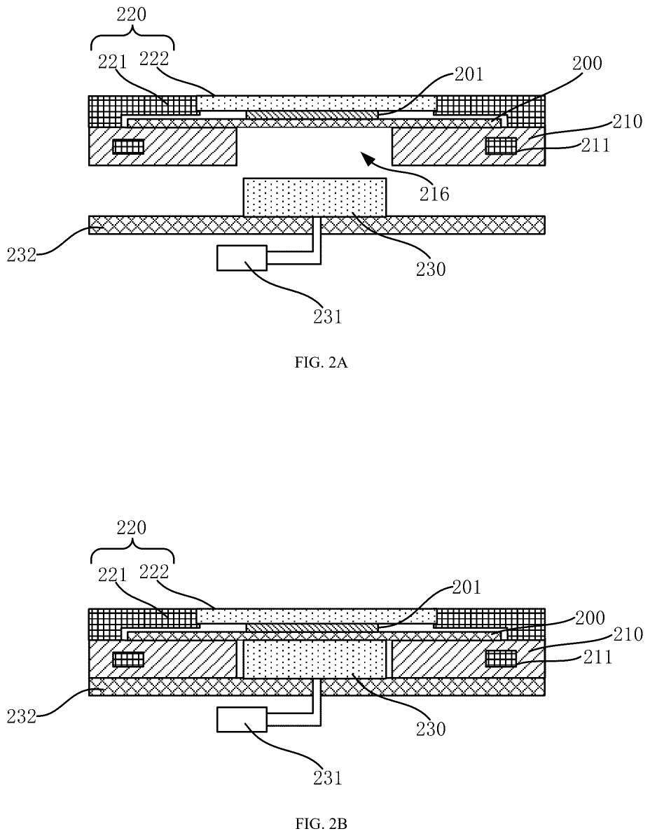

FIGS. 1A to 1C illustrate a bonding apparatus during a bonding step according to a first embodiment of the present application. In particular, FIG. 1A illustrates a side view of the bonding apparatus, FIG. 1B illustrates a top view of a jig of the bonding apparatus shown in FIG. 1A, and FIG. 1C illustrates a top view of a top cover 120 of the bonding apparatus shown in FIG. 1A.

As shown in FIG. 1A, a bonding apparatus is provided, which may be used for bonding a semiconductor die 101 onto a substrate 100 such as a printed circuit board during a bonding process, for example, during a laser assisted bonding (LAB) process. A semiconductor die 101 is mounted on the substrate 100 at its center, for example, with solder paste (not shown) formed between the substrate 100 and the semiconductor die 101 to electrically and mechanically connect the two. In some embodiments, the semiconductor die 101 may include a flip chip. Preferably, the semiconductor die 101 may include a System on a Chip (SOC) die which generally has a big size. Multiple sets of conductive pads can be formed on a top surface of the substrate 100 for the mounting of the semiconductor die 101 on the substrate 100. In some embodiments, additional conductive pads may be formed on a bottom surface of the semiconductor die 101, which also facilitates the mounting of the substrate 100 on the semiconductor die 101 via the solder paste. The bonding apparatus further includes a laser source 140 disposed above the substrate 100 and the semiconductor die 101. The laser source 140 may emit a laser beam to the substrate 100 and the semiconductor die 101 where the laser energy can be absorbed and converted into heat. For the purpose of illustration, in FIG. 1A, the bonding apparatus is implementing a bonding step during which the semiconductor die 101 is being bonded onto the substrate 100, and the solder paste between the semiconductor die 101 and the substrate 100 can be heated and reflowed to form solder bumps which forms sufficient bonding between the semiconductor die 101 and the substrate 100.

The bonding apparatus includes a jig 110 with a passage passing therethrough at a center of the jig 110. During the bonding step, the substrate 100 and the semiconductor die 101 disposed thereon may be placed on the jig 110, and be supported by the jig 110 at the periphery of the substrate 100. In the embodiment shown in FIG. 1A, the bonding apparatus further includes a bonding platform having a bottom cover 132 and a supporting block 130 attached on the bottom cover 132. During the bonding step, the supporting block 130 may be accommodated within the passage of the jig 110 to hold the substrate 100 along with the jig 110. In some embodiments, a height of the supporting block 130 may be approximately the same as that of the jig 110, such that the bottom cover 132 may be attached to a bottom surface of the jig 110 when the supporting block 130 is holding the substrate 100. The bottom cover 132 provides additional mechanical support to hold the jig 110 and component(s) thereon. Furthermore, the supporting block 130 may have air vents which may be distributed across the whole supporting block 130. The air vents are fluidly coupled to a vacuum source 131 to apply a vacuum pressure to absorb and hold the substrate 100 during the bonding step. In some embodiments, the air vents may include a plurality of pores distributed across the whole supporting block 130 to provide a uniform vacuum pressure. In some other embodiments, the air vents may include interconnected channels or pipelines therebetween. The vacuum pressure applied by the supporting block 130 can reduce the stress of the substrate 100 and thus improve the potential warpage issue.

Referring to FIG. 1A in conjunction with FIG. 1B, the jig 110 may have a rectangular layout, which may be similar to a shape of the substrate 100. In some other embodiments, the jig 110 may have other shaped layouts, such as a circle, a hexagon or an octagon, as long as the substrate 100 can be supported properly on the jig 110. Furthermore, at least a magnet 111 is embedded within the jig 110. In some embodiments, the magnet(s) 111 may include at least one material from iron, nickel and cobalt and their alloys, some alloys of rare-earth metals, and some naturally occurring minerals such as lodestone. Preferably, the magnet 111 may include SmCo. Furthermore, the magnets 111 are preferably uniformly distributed in the jig 110, for example, at or close to four edges of the jig 110. In the embodiment shown in FIG. 1B, two magnets 111 are arranged at each of the four edges of the jig 110. The magnets 111 may extend within the jig 110 for a thickness of the jig 110, that is, both top surfaces and bottom surfaces of the magnets 111 may be exposed from the jig 110 such that the magnets 111 can be closer to the top cover 120 when it is placed on the jig 110. In some other embodiments, only the top surfaces of the magnets 110 may be exposed from the jig 110. It can also be appreciated that the magnets 111 may be embedded within an interior of the jig 110 without their top surfaces exposed from the jig 110, but are sufficiently close to the top cover 120 to allow for an appropriate magnetic field that can attract the jig 110 and the top cover 120 (e.g., made of stainless steel) close to each other. In some other embodiments, the magnets 111 may be formed as a single piece such as a loop surrounding the passage, or be formed in an array of magnets 111 that are uniformly distributed across the whole jig 110 to provide a stronger magnetic field.

Furthermore, as shown in FIG. 1B, the jig 110 may also include one or more supporting pin(s) 113 on a front surface of the jig 110. The supporting pin(s) 113 may be used for securing the jig 110 with the top cover 120, which will be illustrated later.

Still referring to FIG. 1A, the bonding apparatus further includes the top cover 120. During the bonding step, the top cover 120 covers both of the substrate 100 and the semiconductor die 101 to reduce potential warpage issues of the substrate 100 and the semiconductor die 101. To be more specific, the top cover 120 includes a clamping component 121 attached to the jig 110 which covers a portion of the substrate 100 at its periphery. In some embodiments, a peripheral portion of the clamping component 121 extends downward to surround a lateral surface of the substrate 100, and thus the substrate 100 may be clamped firmly between the clamping component 121 and the jig 110 to avoid undesired displacement during the bonding step. As shown in FIG. 1C, the clamping component 121 may have a layout similar to the jig 110, so as to mate with the jig 110. As mentioned above, the clamping component 121 includes carbon steel, stainless steel or other similar ferromagnetic materials, which can be attracted by the magnet(s) embedded within the jig 110 when the top cover 120 is attached to the jig 110. Furthermore, the clamping component 121 may include one or more slot(s) through the top cover 120 which mate with the one or more supporting pin(s) on the jig 110 in shape and position, so as to receive the respective supporting pin(s). As such, the clamping component 121 can be firmly fixed to a top surface of the jig 110 without displacement. In other words, the clamping component 121 and the jig 110 may be connected as an integral piece with a portion of the clamping component 121 fixed at a certain height to cover a portion of the substrate 100. When the substrate 100 is heated during the bonding step, the substrate 100 may bend towards the clamping component 121 and thus exert a force to the clamping component 121. Since the clamping component 121 is immobilized and fixed in place, a portion of the clamping component 121 covering the substrate 100 may press the substrate 100 against the jig 110 in response to the force exerted by the substrate 100, which reduces warpage of the substrate 100. In some embodiments, a tiny gap may exist between the clamping component 121 and a top surface and/or a lateral surface of the substrate 100 before the substrate 100 is heated, so as to allow for a small amount of expansion of the substrate 100 during the bonding step. It can also be appreciated that the clamping component 121 may be in direct contact with the substrate 100 to provide a greater pressure to the substrate 100.

Moreover, the clamping component 121 has an opening at its center which is capable of accommodating and exposing the whole semiconductor die 101, as the semiconductor die 101 is mounted on and protrudes from the substrate 100. The top cover 120 further includes a light pervious component 122 having a size and a shape mating with that of the opening, which allows for the light pervious component 122 to be accommodated within the opening and thus cover the semiconductor die 101. In some embodiments, the light pervious component 122 may be fixed on an inner wall of the opening, as a part of the top cover 120, while the clamping component 121 functions as the other part of the top cover 120. In this way, the substrate 100 and the semiconductor die 101 can be clamped between the top cover 120 and the jig 110 firmly. To be more specific, the light pervious component 122 is capable of allowing a laser beam to pass therethrough to the semiconductor die 101 during the bonding step. As such, heat radiated to the semiconductor die 101 may still be sufficient to heat the semiconductor die 101 and the solder paste between the semiconductor and the substrate 100, so as to form solder bumps and thus bond the semiconductor die 101 onto the substrate 100. In some embodiments, the laser beam emitted by the laser source 140 may be an infrared radiation, which has a wavelength ranging between 900 nm and 1000 nm. Preferably, the wavelength may be 980 nm. The light pervious component 122 may include fused silica, CaF₂, MgF₂, crystal quartz or ZnSe, which allows for transmission of the laser radiation with the specific wavelength. In some other embodiments, the wavelength of the laser radiation may change depending on the laser source 140 used in the bonding step. Accordingly, the material of the light pervious component 122 may change with the laser radiation used.

Still referring to FIG. 1A, the light pervious component 122 is fixed within the opening of the clamping component 121. Since the clamping component 121 is attracted by the magnet(s) 111 within the jig 110, the light pervious component 122 is held and immobilized in place firmly by the clamping component 121 at a certain distance to the semiconductor die 101. In some embodiment, the light pervious component 122 has a size larger than that of the semiconductor die 101, which covers the whole semiconductor die 101 when the top cover 120 is attached to the jig 110. It can also be appreciated that the light pervious component 122 may have a same or relatively smaller size than that of the semiconductor die 101.

During the bonding step, when the laser beam passes through the light pervious component 122 to the semiconductor die 101 to heat the semiconductor die 101, the semiconductor die 101 may bend towards the light pervious component 122 and thus exert a force to it. Similarly as the clamping component 121, the light pervious component 122 covering the semiconductor die 101 may press the semiconductor die 101 against the substrate 100 in response to the force exerted by the semiconductor die 101, which reduces warpage of the semiconductor die 101. In this way, the light pervious component 122 can not only ensure sufficient heat to reach the semiconductor die 101, but also reduces warpage of the semiconductor die 101. Moreover, the light pervious component 122 may prevent external contaminants from reaching and being attached to the semiconductor die 101 and the substrate 100, which reduces defects in a device so produced and improves the bonding performance of the device.

In some embodiments, the height of the light pervious component 122 may determine a total height of the device so produced after the bonding step. In some embodiments, the light pervious component 122 may be in direct contact with the semiconductor die 101 to provide a greater pressure to the semiconductor die 101 and keep the height of the solder bumps at a controlled value. The distance between a bottom surface of the light pervious component 122 and a top surface of the semiconductor die 101 should be designed with a total height of the substrate 100, the semiconductor die 101, and the solder bumps to be formed after the bonding step taken into account. In some other embodiments, a small amount of warpage or expansion of the semiconductor die 101 and the substrate 100 may be allowed. In such case, a tiny gap may exist between the light pervious component 122 and a top surface of the semiconductor die 101 before the semiconductor die 101 is heated. The distance between the bottom surface of the light pervious component 122 and the top surface of the semiconductor die 101 can be designed with a total height of the substrate 100, the semiconductor die 101, the solder bumps to be formed and the warpage of the semiconductor die 101 and the substrate 100 that may be allowed during the bonding step taken into account. In this way, the light pervious component 122 also serves as a limit to control the height of the solder bumps and/or the warpage of the semiconductor die 101 and the substrate 100.

In some embodiments, the bottom surface of the light pervious component 122 may be orientated with relative to the top surface of the semiconductor die 101 to meet various requirements of the bonding step. For example, a plurality of tiny slots may be formed on a lateral surface of the inner wall of the opening within the clamping component 121, which are arranged at different heights. The light pervious component 122 may include at least one protrusion extending outward from a lateral surface of the light pervious component 122. Each of the at least one protrusion may be received within one of the tiny slots to fix the light pervious component 122 at a desired distance from the semiconductor die 101. For different bonding steps, the protrusion(s) of the light pervious component 122 may be transferred into different slot(s) to adjust the distance between the bottom surface of the light pervious component 122 and the top surface of the semiconductor die 101.

In some embodiments, the light pervious component 122 may have a uniform thickness. In some other embodiments, the light pervious component 122 may have a smaller thickness for areas aligned with the solder paste than the other areas of the light pervious component 122, so as to allow for more laser radiation passing therethrough to heat the semiconductor die 101 and the underlying solder paste. It can also be appreciated that the light pervious component 122 may include openings which are aligned with the solder paste. As such, the light pervious component 122 may ensure a sufficient amount of heat radiation to reflow the solder paste and form the solder bumps while reducing the warpage of the semiconductor die 101 and the substrate 100 during the bonding step.

Therefore, during the step of bonding the semiconductor die 101 onto the substrate 100 using the bonding apparatus illustrated in FIGS. 1A to 1C, the warpage of the semiconductor die 101 and the substrate 100 may be reduced by attaching the top cover 120 having the clamping component 121 and the light pervious component 122 to the jig 110. Since the top cover 120 is attracted by the jig 110 firmly without displacement during the bonding step, the top cover 120 may press the semiconductor die 101 and the substrate 100 towards the jig 110, without the need of a separate compression process otherwise implemented by a compression tool, which is generally used in a conventional LCB process. Thus, the cost of manufacturing such device is reduced.

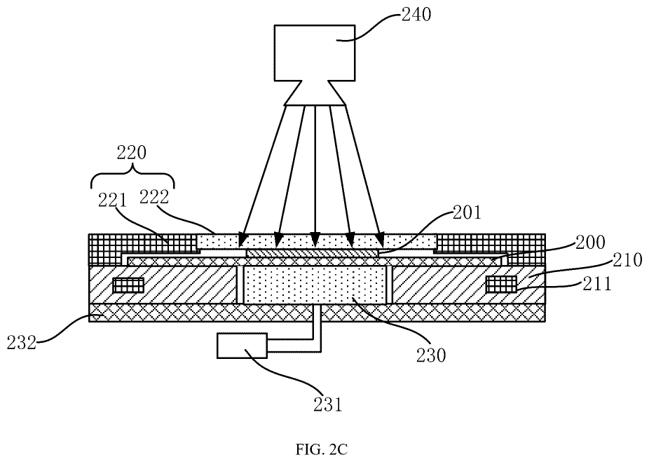

FIGS. 2A to 2C illustrate various steps of a bonding method implemented by a bonding apparatus according to a second embodiment of the present application. For example, the bonding method may be implemented by the bonding apparatus shown in FIGS. 1A to 1C.

As shown in FIG. 2A, a bonding apparatus is used for conducting the process of bonding a semiconductor die 201 onto a substrate 200. To be more specific, the bonding apparatus includes a jig 210, a top cover 220 mounted above the jig 210, and a laser source 240 disposed above the top cover 220. The top cover 220 has a clamping component 221 and a light pervious component 222. The details of the bonding apparatus, the semiconductor die 201 and the substrate 200 may be similar to those illustrated with respect to the embodiments shown in FIGS. 1A to 1C, which will not be elaborated in detail here for simplicity.

Referring to FIG. 2A, the substrate 200 and the semiconductor die 201 are stacked between the top cover 220 and the jig 210. A solder paste may be applied between the substrate 200 and the semiconductor die 201, which is to be heated and reshaped to form solder bumps during a subsequent bonding step. In some embodiments, a flux material may also be applied along with the solder paste. To be more specific, the substrate 200 with a semiconductor die 201 mounted thereon is placed on the jig 210, with a periphery of the substrate 200 supported by the jig 210. Next, a top cover 220 is attached onto the jig 210, which can be attracted by magnet(s) 211 embedded within the jig 210 to avoid displacement between the top cover 220 and the jig 210. In some embodiments, the clamping component 221 is disposed on the jig 210, which covers a portion of the substrate 200, and the light pervious component 122 covers the semiconductor die 201. It can also be appreciated that the clamping component 221 may first be attached on the jig 210 and the light pervious component 122 may be disposed within an opening of the clamping component 221 in a subsequent process.

As shown in FIG. 2A, the jig 210 further includes a passage 216 below the substrate 200. A bonding platform having a bottom cover 232 and a supporting block 230 attached on the bottom cover 232 may be provided, which is spaced away from the jig 210. In some embodiments, the supporting block 230 has air vents across the supporting block 230 and are fluidly coupled to a vacuum source 231.

Next, the bonding platform is moved towards the jig 210 and finally be attached to the jig 210 at a different side from the top cover 220, as shown in FIG. 2B. In this case, the supporting block 230 may be accommodated within the passage 216 of the jig 210 to hold the substrate 200, and the bottom cover 232 is attached on a bottom surface of the jig 210. The bottom cover 232 may include a same material as that of the clamping component 221, which may be attracted by the magnet(s) 211 within the jig 210.

Next, the bonding step is conducted to bond the semiconductor die 201 onto the substrate 200. To be more specific, the vacuum source 231 may be turned on to apply a vacuum pressure to absorb and secure the substrate 200 through the air vents. As shown in FIG. 2C, the laser source 240 may be turned on to emit a laser beam to the semiconductor die 201. The laser beam passes through the light pervious component 122 to the semiconductor die 201 to heat and reshape the solder paste, so as to form desired solder bumps and build sufficient bonding between the semiconductor die 201 and the substrate 200. During the bonding step, the clamping component 221 may press a portion of the substrate 200 against the jig 210, and the light pervious component 122 may press the semiconductor die 201 against the substrate 200, such that the warpage of the semiconductor die 201 and the substrate 200 may be reduced to improve bonding quality between the semiconductor die 201 and the substrate 200, thereby enhancing the performance of the device so produced. After the bonding step, the bonding platform may be removed from the jig 210 to create sufficient room for a subsequent process. In some embodiments, a subsequent underfilling or encapsulation process may be performed on the bonded semiconductor die 201 and substrate 200.

The bonding method using the bonding apparatus illustrated above may be used in any chip assembly process which desires less warpage when exposed to heating processes such as bonding and reflowing, and thus results in a controlled package thickness, better device performance and a larger process window.

While the exemplary bonding apparatus of the present application is described in conjunction with corresponding figures, it will be understood by those skilled in the art that modifications and adaptations to the bonding apparatus may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A bonding apparatus, comprising:
a jig configured for supporting a substrate at its periphery, wherein the substrate has a semiconductor die mounted thereon;
a top cover operably attached to the jig and configured for covering the substrate and the semiconductor die when the top cover is attached to the jig, wherein the top cover comprises:
a clamping component operably attached to the jig and configured for covering a portion of the substrate to reduce warpage of the substrate when the top cover is attached to the jig, wherein the clamping component comprises an opening at its center and configured for accommodating and exposing the semiconductor die; and
a light pervious component mounted within the opening and configured for covering the semiconductor die to reduce warpage of the semiconductor die and allowing a laser beam to pass therethrough to the semiconductor die when the top cover is attached to the jig; and
a laser source configured for emitting a laser beam that passes through the light pervious component to the semiconductor die.

2. The bonding apparatus of claim 1, wherein the jig comprises at least a magnet embedded within the jig and configured for attracting the clamping component when the top cover is attached to the jig.

3. The bonding apparatus of claim 2, wherein the clamping component comprises carbon steel or stainless steel.

4. The bonding apparatus of claim 1, wherein the light pervious component comprises fused silica, CaF₂, MgF₂, crystal quartz or ZnSe.

5. The bonding apparatus of claim 4, wherein the laser beam emitted by the laser source comprises infrared radiation with a wavelength ranging between 900 nm and 1000 nm.

6. The bonding apparatus of claim 1, wherein the jig comprises a passage below the substrate, and the bonding apparatus further comprises:
a bonding platform operably attached to the jig at a different side from the top cover, and configured for supporting the substrate along with the jig when the bonding platform is attached to the jig, wherein the bonding platform comprises:
a bottom cover; and
a supporting block attached on the bottom cover and configured for being accommodated within the passage of the jig such that the supporting block holds the substrate when the bonding platform is attached to the jig.

7. The bonding apparatus of claim 6, wherein the supporting block has air vents being fluidly coupled to a vacuum source to apply a vacuum pressure to the substrate when the supporting block is holding the substrate.

8. A bonding method, wherein the bonding method is implemented by a bonding apparatus comprising: a jig; a top cover above the jig, wherein the top cover comprises a clamping component having an opening, and a light pervious component disposed within the opening; and a laser source, and wherein the method comprises:
placing a substrate having a semiconductor die mounted thereon between the top cover and the jig with the jig supporting the substrate at its periphery and the top cover attached to the jig, wherein the clamping component covers a portion of the substrate and the light pervious component covers the semiconductor die; and
emitting a laser beam to the semiconductor die through the light pervious component via the laser source to bond the semiconductor die onto the substrate via solder bumps, wherein the clamping component presses a portion of the substrate against the jig to reduce warpage of the substrate and the light pervious component presses the semiconductor die against the substrate to reduce warpage of the semiconductor die.

9. The bonding method of claim 8, wherein the light pervious component comprises fused silica, CaF₂, MgF₂, crystal quartz or ZnSe.

10. The bonding method of claim 9, wherein the laser beam comprises infrared radiation with a wavelength ranging between 900 nm and 1000 nm.

11. The bonding method of claim 8, wherein the jig comprises a passage below the substrate, and before emitting a laser beam to the semiconductor die through the light pervious component via the laser source, the method further comprises:
attaching a bonding platform having a bottom cover and a supporting block attached on the bottom cover to the jig at a different side from the top cover, so as to support the substrate along with the jig, wherein the supporting block is accommodated within the passage of the jig such that the supporting block holds the substrate.

12. The bonding method of claim 11, wherein the supporting block has air vents being fluidly coupled to a vacuum source, and the method further comprises: applying a vacuum pressure to the substrate when the supporting block is holding the substrate.

13. The bonding method of claim 11, wherein after bonding the semiconductor die onto the substrate, the method further comprises: removing the bonding platform from the jig.
